(19) United States
(12) Patent Application Publication
(10) Pub. No.: US 2025/0128351 A1
(43) Pub. Date: Apr. 24, 2025

(54) METHOD FOR MULTI-BEAM LASER SCRIBING OF THIN-FILM SOLAR CELL

(71) Applicant: Shenzhen Qinghong Laser Technology Co., Ltd, Shenzhen (CN)

(72) Inventors: Kun GAO, Shenzhen (CN); Shuling YE, Shenzhen (CN); Cheng LI, Shenzhen (CN); Fan ZENG, Shenzhen (CN)

(21) Appl. No.: 18/989,572

(22) Filed: Dec. 20, 2024

(30) Foreign Application Priority Data
May 30, 2024 (CN) 202410683712.1

(51) Int. Cl. B23K 26/067; B23K 26/046; B23K 26/082

(52) U.S. Cl. CPC B23K 26/067; B23K 26/046; B23K 26/082

(57) ABSTRACT

A method for multi-beam laser scribing of a thin-film solar cell is provided. A laser beam output by a laser is split by an optical path unit or a splitter assembly into multiple sub-beams. The multiple sub-beams are focused by a laser-focusing scribing head assembly to form a laser focus on the thin-film solar cell. The thin-film solar cell is fixed on a bearing platform or clamped by a clamping mechanism, and driven by a drive module to reciprocate in a direction perpendicular to an output direction of the laser-focusing scribing head assembly to create a first scribe line. A position of the laser-focusing scribing head assembly is switched, and the thin-film solar cell is driven to reciprocate again to create a second scribe line. The fume and dust generated during the scribing process are removed through a fume-fume-dust extraction port corresponding to the scribing head assembly.

### CROSS-REFERENCE TO RELATED APPLICATIONS

This application claims the benefit of priority from Chinese Patent Application No. 202410683712.1, filed on May 30, 2024. The content of the aforementioned application, including any intervening amendments made thereto, is incorporated herein by reference in its entirety.

### TECHNICAL FIELD

This application relates to laser processing and automatic control, and more particularly to a method for multi-beam laser scribing of a thin-film solar cell.

### BACKGROUND

As the third-generation solar cells, thin-film solar cells have attracted considerable interest due to their excellent performances, and mainly include cadmium telluride (CdTe), copper indium gallium selenide (CIGS) and perovskite-based thin-film solar cells. The manufacturing process of thin-film solar cells includes three scribing steps (known as P1, P2 and P3), which all involve the laser scribing equipment. These scribing steps are extremely critical, which require the straightness and parallelism of P1, P2 and P3 scribes to reach the micron level. Precise scribing can effectively reduce the dead area, and is of great significance for improving the cell conversion efficiency. However, the laser scribing equipment accounts for a large proportion of the entire production investment. Therefore, how to design and develop a laser scribing system with excellent performance, high efficiency and low cost has become a top priority in the field of thin-film solar cells.

The glass substrates of thin-film solar cells are large in area. For example, for a glass substrate with a length of 2.4 m and a width of 1.2 m, more than 200 scribes may be created in a single P1 scribing step. Therefore, increasing the number of scribing beams in the scribing device or even integrating multiple scribing devices to simultaneously perform the scribing step has been considered as an optimal solution to improve the production efficiency.

### SUMMARY

An object of the disclosure is to provide a method for multi-beam laser scribing of a thin-film solar cell, which can satisfy the requirement of increasing the number of scribing beams in a scribing device or even integrating multiple scribing devices to simultaneously perform the scribing step.

In order to achieve the above object, the following technical solutions are adopted.

This application provides a method for multi-beam laser scribing of a thin-film solar cell by using a laser scribing system, the laser scribing system comprising a laser, an optical path unit, a beam splitter assembly, a laser-focusing scribing head assembly, a motion module and a drive module.

According to the above arrangement, a laser beam is output by a laser, and split by the optical path unit into two laser sub-beams, or two laser beams are output by two lasers, respectively, and reflected by two reflectors to enter two beam splitter assemblies; the laser beam is split by the beam splitter assembly into 4-12 laser sub-beams to enter 1-6 laser-focusing scribing head assemblies, respectively. In some embodiments, the 1-4 laser-focusing scribing head assemblies are respectively arranged at plurality of bearing platforms on the motion module. Each of the 1-4 laser-focusing scribing head assemblies is configured to output 6-12 focused laser beams to form a laser focus on the thin-film solar cell. In some embodiments, the thin-film solar cell is fixed on a carrying platform of the drive module by vacuum suction, and is driven by the drive module to reciprocate in a direction perpendicular to an output direction of the laser-focusing scribing head assembly to create a first scribe line, wherein a film surface of the thin-film solar cell faces upward. In some embodiments, the thin-film solar cell is held by a roller or air flow; and a side of the thin-film solar cell is clamped by a clamping mechanism of the drive module, and the thin-film solar cell is driven by the drive module to reciprocate, wherein a film surface of the thin-film solar cell faces upward. In order to ensure that there is no excessive fume and dust during the scribing process, a plurality of fume-dust extraction ports are arranged above the thin-film solar cell, and are in one-to-one correspondence with the laser-focusing scribing head assemblies. The plurality of fume-dust extraction ports are each configured to be driven by an independently movable fume-dust extraction shaft. The plurality of fume-dust extraction ports are configured to maintain a relative position with a corresponding laser-focusing scribing head assembly during scribing, and move synchronously with a corresponding laser-focusing scribing head assembly for position switching when switching a scribing path. The reciprocating motion of the thin-film solar cell and the switching movement of the scribing path of the laser-focusing scribing head assembly are coordinated to achieve the scribing of the entire thin-film solar cell.

A single or dual laser is adopted to output the laser beam. The laser beam can be effectively split into two or more laser sub-beams by virtue of the design of the optical path unit. The beam splitter assembly is the core part of the present disclosure, which is adopted for further splitting the laser beam into 4-12 beams, thereby providing sufficient laser sources for subsequent laser processing. Each laser-focusing scribing head assembly is provided with an independently powered bearing platform mounted on the motion module, so as to ensure the accuracy and flexibility of laser processing. Each laser-focusing scribing head assembly can output 6-12 focused laser beams, so that the laser focus can accurately act on the thin-film solar cell, so as to achieve efficient and accurate scribing processing.

The thin-film solar cell is fixed on the carrying platform of the drive module by vacuum suction to ensure its stability and accurate position. A movement direction of the thin-film solar cell is perpendicular to the arrangement direction of the laser scribing head assemblies. The reciprocating motion of the thin-film solar cell and the switching movement of the scribing path of the laser-focusing scribing head assembly are coordinated to achieve the scribing of the entire thin-film solar cell.

The drive module is a linear motor, a servo motor-screw module or a synchronous belt module.

The plurality of fume-dust extraction ports are arranged above the thin-film solar cell, and are in one-to-one correspondence with the laser scribing head assemblies, which effectively reduces fume and dust that may be generated during the scribing process.

Such a fume and dust treatment design not only improves the processing quality, but also reflects the environmental protection concept of the technique.

The entire process is highly automated, and the high efficiency and high precision of the laser scribing processing is achieved by the coordination of motors, modules and laser scribing head assemblies.

This technical solution is suitable for large-scale, high-efficiency solar cell production lines, improving production efficiency and product quality.

The technical solution provided by this application has the following beneficial effects.

The glass motion scribing is combined with the flight light path switching, and the efficiency of the glass air flotation motion is not low, with a motion speed reaching 2.5 m/s and a motion acceleration reaching 1.5 m/s². At the same time, the flight light path only needs to cover a length of a shorter side of a product, which is 1.2 m shorter than that of a longer side. This indicates a shorter motion time, ensuring both efficient production and high stability. At the same time, the fume-dust extraction shafts are arranged separately form each other, and the laser scribing head assemblies are modularly designed, which is convenient for the switching among 8, 12, 16, 24 and 36 focused beams. In this way, the requirements of increasing the number of scribing beams in the scribing device or even integrating multiple scribing devices to simultaneously perform multiple scribing operations can be satisfied.

In summary, the laser scribing technique provided by the present disclosure has broad application prospects in the field of thin-film solar cells by virtue of its high efficiency, precision and automation.

### BRIEF DESCRIPTION OF THE DRAWINGS

FIG. 1 is a schematic diagram of a method for multi-beam laser scribing of a thin-film solar cell in accordance with Embodiment 1 of the present disclosure;

FIG. 2 is a schematic diagram of a method for multi-beam laser scribing of a thin-film solar cell in accordance with Embodiment 2 of the present disclosure; and

FIG. 3 is a schematic diagram of a method for multi-beam laser scribing of a thin-film solar cell in accordance with Embodiment 3 of the present disclosure.

### DETAILED DESCRIPTION OF EMBODIMENTS

The technical core of this application is to satisfying the requirement of increasing the number of scribing beams in a scribing device or even integrating multiple scribing devices to simultaneously perform multiple scribing operations.

This application will be described in detail below with reference to the embodiments and accompanying drawings to make the technical solutions of this application clearer.

### EMBODIMENT 1

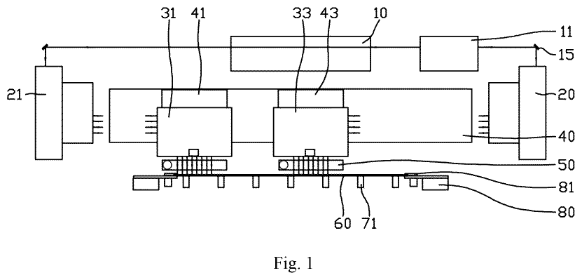

As shown in FIG. 1, a laser beam is output by a laser 10, and is split into two laser beams by an optical path unit 11. The two laser beams are reflected by two reflectors 15 into a left beam splitter assembly 21 and a right beam splitter assembly 20 for energy splitting, respectively. After energy splitting, 4 laser beams equal in power are output from each of the left beam splitter assembly 21 and the right beam splitter assembly 20 into a first laser-focusing scribing head assembly 31 and a third laser-focusing scribing head assembly 33, respectively. The first and third laser-focusing scribing head assemblies 31 and 33 are respectively mounted on a first bearing platform 41 and a second bearing platform 43 of a motion module 40. The first and second bearing platforms 41 and 43 are configured to be independently powered and moved. 8 focused laser beams are output downwardly from each of the first and third laser-focusing scribing head assemblies 31 and 33 to form a laser focus on a thin-film solar cell 60. The thin-film solar cell 60 is held by a roller 71. A side of the thin-film solar cell 60 is clamped by a clamping mechanism 81 of a linear motor module 80, such that the thin-film solar cell 60 is driven to reciprocate in a direction perpendicular to an output direction of the first and third laser-focusing scribing head assemblies 31 and 33. The first and third laser-focusing scribing head assemblies 31 and 33 each have a track following function and a focus following function. A focus of each laser beam is independently electrically adjusted, a line spacing is independently and electrically adjusted, and diffractive optical element (DOE) spot shaping is performed on each laser beam to achieve a flat-toped spot or multi-spots. The scribing is performed by the first and third laser-focusing scribing head assemblies 31 and 33 as planned, with the specific process as follows. The side of the thin-film solar cell 60 is clamped by the clamping mechanism 81 of the linear motor module 80 to drive the thin-film solar cell 60 to reciprocate in the direction perpendicular to the output direction of the first and third laser-focusing scribing head assemblies 31 and 33 to create a first scribe line according to a longer side contour of the product or a scribing trajectory of the previous process. The first and third laser-focusing scribing head assemblies 31 and 33 are switched to step one sub-cell pitch and stopped. The side of the thin-film solar cell 60 is clamped by the clamping mechanism 81 of the linear motor module 80 to drive the thin-film solar cell 60 to reciprocate to create a second scribe line. The steps to create the first and second scribe lines are repeated to complete the scribing of the whole product.

Two fume-dust extraction ports 50 are arranged above the thin film solar cell 60. The two fume-dust extraction ports 50 are each driven by an independently movable fume-dust extraction shaft. The two fume-dust extraction ports correspond to the first and third laser-focusing scribing head assemblies 31 and 33, respectively, and are configured to independently moved. During scribing, a fume-dust extraction port maintains a relative position with a corresponding laser-focusing scribing head assembly, and moves synchronously with the corresponding laser-focusing scribing head assembly for position switching when switching a scribing path.

### EMBODIMENT 2

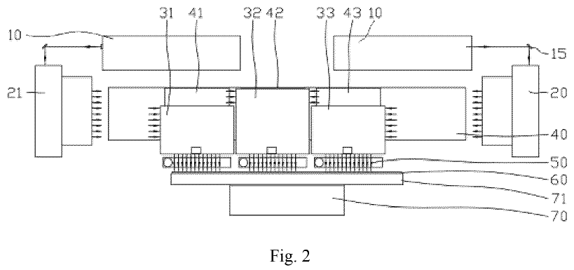

As shown in FIG. 2, two laser beams are independently output by two lasers 10 into a left beam splitter assembly 21 and a right beam splitter assembly 20 for splitting, respectively. 9 laser beams are output by the left beam splitter assembly 21, of which 6 lower laser beams enter a first laser-focusing scribing head assembly 31, and 3 upper laser beams enter a second laser-focusing scribing head assembly 32. 9 laser beams are output by the right beam splitter assembly 20, of which 6 lower laser beams enter a third laser-focusing scribing head assembly 33, and 3 upper laser beams enter the second laser-focusing scribing head assembly 32. The first, second and third laser-focusing scribing head assemblies 31, 32 and 33 are respectively mounted on bearing platforms 41, 42 and 43 of a motion module 40. The first, second and third laser-focusing scribing head assemblies 31, 32 and 33 are configured to be independently powered and moved. In this embodiment, 12 focused laser beams are output downwardly from each of the first, second and third laser-focusing scribing head assemblies 31, 32 and 33 to form a laser focus on a thin-film solar cell 60. The thin-film solar cell 60 is fixed on a carrying platform 71 on a linear motor module 70 by vacuum suction. Three fume-dust extraction ports 50 are arranged above the thin film solar cell 60. The three fume-dust extraction ports 50 are each driven by an independently movable fume-dust extraction shaft. The three fume-dust extraction ports 50 correspond to the first, second and third laser-focusing scribing head assemblies 31, 32 and 33, respectively, and are configured to be independently moved. During scribing, a fume-dust extraction port maintains a relative position with a corresponding laser-focusing scribing head assembly, and moves synchronously with the corresponding laser-focusing scribing head assembly for position switching when switching a scribing path.

### EMBODIMENT 3

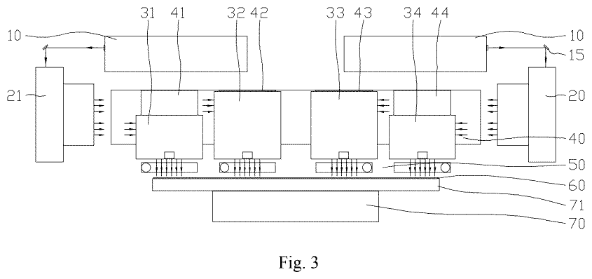

As shown in FIG. 3, two laser beams are independently output by two lasers 10 into a left beam splitter assembly 21 and a right beam splitter assembly 20 for splitting, respectively. 6 laser beams are output by the left beam splitter assembly 21, of which 3 lower laser beams enter a first laser-focusing scribing head assembly 31, and 3 upper laser beams enter a second laser-focusing scribing head assembly 32. 6 laser beams are output by the right beam splitter assembly 20, of which 3 upper laser beams enter a third laser-focusing scribing head assembly 33, and 3 lower laser beams enter a fourth laser-focusing scribing head assembly 34. The first, second, third and fourth laser-focusing scribing head assemblies 31, 32, 33 and 34 are respectively mounted on bearing platforms 41, 42, 43 and 44 of a motion module 40. The bearing platforms 41, 42, 43 and 44 are configured to be independently powered and moved. In this embodiment, 6 focused laser beams are output downward by each of the first, second, third and fourth laser-focusing scribing head assemblies 31, 32, 33 and 34 to form a laser focus on a thin-film solar cell 60. The thin-film solar cell 60 is fixed on a carrying platform 71 on a linear motor module 70 by vacuum suction. Four fume-dust extraction ports 50 are arranged above the thin film solar cell 60. The four dust extraction ports 50 are each driven by an independently movable fume-dust extraction shaft. The four fume-dust extraction ports 50 correspond to the first, second, third and fourth laser-focusing scribing head assemblies 31, 32, 33 and 34, respectively, and are configured to be independently moved. During scribing, a fume-dust extraction port maintains a relative position with a corresponding laser-focusing scribing head assembly, and moves synchronously with the corresponding laser-focusing scribing head assembly for position switching when switching a scribing path.

In addition, each of the laser-focusing scribing head assemblies has a modularized structure, and is configured to be switched to output 8, 12, 16, 24 or 36 focused laser beams, so as to satisfy the requirement of increasing the number of scribing beams in a scribing device or even integrating multiple scribing devices to simultaneously perform multiple scribing operations.

The embodiments described above are merely illustrative of the present application, and are not intended to limit the scope of the present application, enabling those skilled in the art to understand or implement the present disclosure.

Although detailed descriptions have been made with reference to the above embodiments, modifications for the technical solutions recorded in the above embodiments, or equivalent substitutions for some or all of the technical features made by those of ordinary skill in the art shall fall within the scope of the disclosure defined by the appended claims.

What is claimed is:

1. A method for multi-beam laser scribing of a thin-film solar cell by using a laser scribing system, the laser scribing system comprising a laser, an optical path unit, a beam splitter assembly, a laser-focusing scribing head assembly, a motion module and a drive module, the laser-focusing scribing head assembly being provided on the motion module, the motion module being configured to drive the laser-focusing scribing head assembly to move, and the method comprising:
(1) outputting, by the laser, a laser beam; and splitting, by the optical path unit or the beam splitter assembly, the laser beam into a plurality of laser sub-beams;
(2) focusing, by the laser-focusing scribing head assembly, the plurality of laser sub-beams to form a laser focus on the thin-film solar cell; and
(3) driving, by the drive module, the thin-film solar cell to reciprocate in a direction perpendicular to a laser output direction of the laser-focusing scribing head assembly to create a first scribe line.

2. The method of claim 1, wherein step (3) further comprises:
fixing the thin-film solar cell on a carrying platform of the drive module by vacuum suction, wherein a film surface of the thin-film solar cell faces upward.

3. The method of claim 1, wherein step (3) further comprises:
holding the thin-film solar cell by a roller or air flow, and clamping a side of the thin-film solar cell by a clamping mechanism of the drive module, wherein a film surface of the thin-film solar cell faces upward.

4. The method of claim 1, further comprising:
switching, by the motion module, a position of the laser-focusing scribing head assembly; and repeating step (3) to create a second scribe line on the thin-film solar cell.

5. The method of claim 1, wherein in step (1), the laser beam is split by the optical path unit into two laser sub-beams.

6. The method of claim 1, wherein the number of the laser is two, and the number of the beam splitter assembly is two; and two laser beams are respectively from two lasers to two beam splitter assemblies.

7. The method of claim 1, wherein the laser is a femtosecond fiber laser, a picosecond laser or a nanosecond laser with a power equal to or greater than 100 W.

8. The method of claim 1, wherein in step (1), the laser beam is split by the beam splitter assembly into 4-12 laser sub-beams to enter the laser-focusing scribing head assembly.

9. The method of claim 1, wherein the motion module is provided with a plurality of bearing platforms, and the plurality of bearing platforms are configured to be independently powered and moved; the number of the laser-focusing scribing head assembly is 1-6; 1-6 laser-focusing scribing head assemblies are respectively arranged at the plurality of bearing platforms; and each of the 1-6 laser-focusing scribing head assemblies is configured to output 6-12 focused laser beams.

10. The method of claim 1, wherein the laser-focusing scribing head assembly has a modularized structure, and is configured to be switched to output 8, 12, 16, 24 or 36 focused laser beams.

11. The method of claim 1, wherein the motion module is a linear motor; and the drive module is a linear motor, a servo motor-screw module or a synchronous belt module.

12. The method of claim 1, wherein the laser-focusing scribing head assembly is configured to have a downward laser output, and is located above the thin-film solar cell to process a film surface of the thin-film solar cell.

13. The method of claim 1, wherein the laser-focusing scribing head assembly is configured to have an upward laser output, and is located below the thin-film solar cell to process a glass surface of the thin-film solar cell.

14. The method of claim 9, wherein the laser scribing system further comprises at least one fume-dust extraction port configured to remove dust and fume generated during a scribing process; the at least one fume-dust extraction port is in one-to-one correspondence with the 1-6 laser-focusing scribing head assemblies, and is configured to be independently moved; the at least one fume-dust extraction port is configured to be respectively opposite to the 1-6 laser-focusing scribing head assemblies during a scribing process; and the at least one fume-dust extraction port is configured to moved synchronously with the 1-6 laser-focusing scribing head assemblies when it is required to scribe another scribe line.

15. The method of claim 14, wherein each of the at least one fume-dust extraction port is provided with an extraction shaft, and extraction shafts of the at least one fume-dust extraction port are arranged separately from each other to prevent interfering with an optical path.
